(19) United States
(12) Patent Application Publication
(10) Pub. No.: US 2026/0050134 A1
(43) Pub. Date: Feb. 19, 2026

(54) FIBER PEDESTAL APPARATUS

(71) Applicants: Sercomm Corporation, Taiwan (CN); Sernet (Suzhou) Technologies Corp., Jiangsu (CN)

(72) Inventors: Peter H. WOLFF, Bradenton, FL (US); Donald A JONES, Birmingham, AL (US)

(73) Assignees: Sercomm Corporation, Taiwan (CN); Sernet (Suzhou) Technologies Corp., Jiangsu (CN)

(21) Appl. No.: 19/297,442

(22) Filed: Aug. 12, 2025

Related U.S. Application Data
(60) Provisional application No. 63/684,160, filed on Aug. 16, 2024.

(51) Int. Cl. G02B 6/44; H05K 7/20

(52) U.S. Cl. CPC G02B 6/4447; G02B 6/4459; H05K 7/20127

(57) ABSTRACT

The present disclosure relates generally to a pedestal apparatus. In one embodiment, the pedestal apparatus comprises: a lid component having a first cross sectional area, a base component having a second cross sectional area smaller than the first cross sectional area, and an adapter component configured to connect the lid component to the base component and enclose communication cables running from the base component to the lid component.

### CROSS-REFERENCE TO RELATED APPLICATIONS

This application is entitled to and claims the benefit of priority from U.S. Provisional Application No. 63/684,160, filed Aug. 16, 2024, the entire contents of which are incorporated herein by reference for all purposes.

### TECHNICAL FIELD

This disclosure relates generally to the field of pedestals for communication cables and equipment. More particularly, and without limitation, the present disclosure relates to innovations in pedestal design that accommodate installation of new communication equipment.

### BACKGROUND

The inventors here have recognized several problems associated with upgrading communication equipment. For example, new communication equipment often requires a larger space than existing pedestals can provide. Further, new communication equipment consumes more power and generates more heat than existing pedestals can accommodate. Current techniques for transitioning to new communication equipment involve replacing existing pedestals wholesale with a larger base capable of accepting a larger pedestal lid. However, this approach has significant costs associated with it, including wasting existing pedestal components, interruptions from digging out the existing pedestal, and re-grading after installing the new pedestal. Further, this process can be very disruptive to people living in the vicinity of the pedestal being upgraded and may require approvals from the local home owners association and/or permitting authorities. Therefore, there is a need for a more cost-effective, less intrusive means of accommodating new communication equipment.

### SUMMARY

The present disclosure relates generally to a pedestal apparatus that includes an adapter component allowing an existing pedestal base to be re-used with a larger pedestal lid that accommodates new communication equipment. More particularly, and without limitation, the present disclosure relates to a pedestal apparatus, comprising: a lid component having a first cross sectional area, a base component having a second cross sectional area smaller than the first cross sectional area, and an adapter component configured to connect the lid component to the base component and enclose communication cables running from the base component to the lid component.

Certain aspects of the present disclosure relate to a pedestal apparatus adapter comprising a bottom portion having a first cross sectional area and configured to align with a base component, a top portion having a second cross sectional area larger than the first cross sectional area, the top portion being configured to align with a lid component, and a surface spanning from the bottom portion to the top portion, the surface being configured to enclose communication cables running from the base component to the lid component.

Other aspects of the present disclosure relate to a method of upgrading pedestal equipment, comprising: removing an existing pedestal lid from an existing pedestal base, installing an adapter component configured to accommodate a difference in size between a first cross sectional area of the existing pedestal base and a second cross sectional area of a new pedestal lid, wherein the second cross sectional area is larger than the first cross sectional area. The method may further comprises installing the new pedestal lid.

### BRIEF DESCRIPTIONS OF FIGURES

FIGS. 1a-1b illustrate the existing and new pedestal upgrade processes, consistent with the disclosed embodiments.

FIGS. 2a-2b illustrate exploded views of the pedestal apparatus components, consistent with disclosed embodiments.

FIGS. 3a-3d illustrate the pedestal apparatus venting components and provided heat dissipation, consistent with disclosed embodiments.

FIGS. 4a-4f illustrate example configurations of the pedestal apparatus, consistent with disclosed embodiments.

### DETAILED DESCRIPTION

The present disclosure provides a pedestal apparatus that accommodates new communication equipment while re-using an existing pedestal base. For example, the new communication equipment may include new amplifiers (e.g., next generation line extenders) or node products that are larger and consume more power than existing equipment. In some situations, the new communication equipment may replace existing equipment in an existing pedestal, while in other situations the new communication equipment may be in addition to existing equipment and/or communication taps in an existing pedestal. As described above, the new pedestal apparatus accommodates the new communication equipment's larger size and greater heat generation.

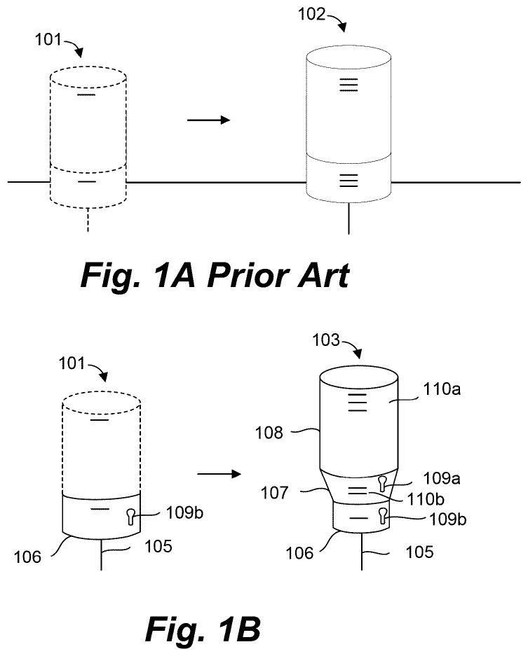

FIGS. 1a-1b illustrate the existing and new pedestal upgrade processes, consistent with the disclosed embodiments. FIG. 1a illustrates the existing pedestal upgrade process, which involves removing the entire existing pedestal 101 and replacing with a new pedestal 102, including a larger diameter, height, and/or greater venting capacity. As described above, this process can be costly and disruptive because all the existing pedestal components are wasted and groundwork is required to dig out and replace the existing pedestal. FIG. 1b illustrates a new pedestal upgrade process provided by the pedestal apparatus of the present disclosure. As shown, an existing pedestal base 106 of existing pedestal 101 may be re-used as part of new pedestal 103. Further, in some embodiments, components of the pedestal base 106 may be re-used as well. For example, in some embodiments, a key mechanism 109b (e.g., keyway or locking mechanism) and a ground support structure 105 (e.g., a rod) may be used in the new pedestal apparatus. In some embodiments, the ground support structure 105 is mounted to the inside of existing pedestal base 106 and may extend through new pedestal 103 to mount the new communication equipment. In some embodiments, pedestals 101, 102, and 103 may be constructed from at least one of: plastic, fiberglass, or steel. In some embodiments, pedestals 101, 102, and/or 103 may be constructed through manufacturing techniques such as injection molding, open molding, forming, bending, drawing, cutting, and/or milling.

The new pedestal 103 includes a new pedestal lid 108. The new pedestal lid 108 may be larger than the existing pedestal base 106. In some embodiments the new pedestal lid 108 cross sectional area may be 120%-250% larger than the existing pedestal base 106 cross sectional area. In some embodiments, both the existing and new pedestals may have a circular shape and the existing pedestal base 106 may have a diameter of 7-11 inches, while the new pedestal lid has a diameter of 12-14 inches. In some embodiments, the new pedestal lid 108 may be taller than the removed lid of existing pedestal 101.

The new pedestal lid 108 may include one or more vents 110a to accommodate the increased heat generation of the new communication equipment. In some situations, these vents 110a may be larger than vents on existing pedestal 101. For example, vents 110a may be longer and/or include a larger opening area than vents on the removed lid of existing pedestal 101. In other embodiments, pedestal 101 may not have included any vents. Vent(s) 110a allow air to flow through the new pedestal lid 108 to cool the new communication equipment through convection.

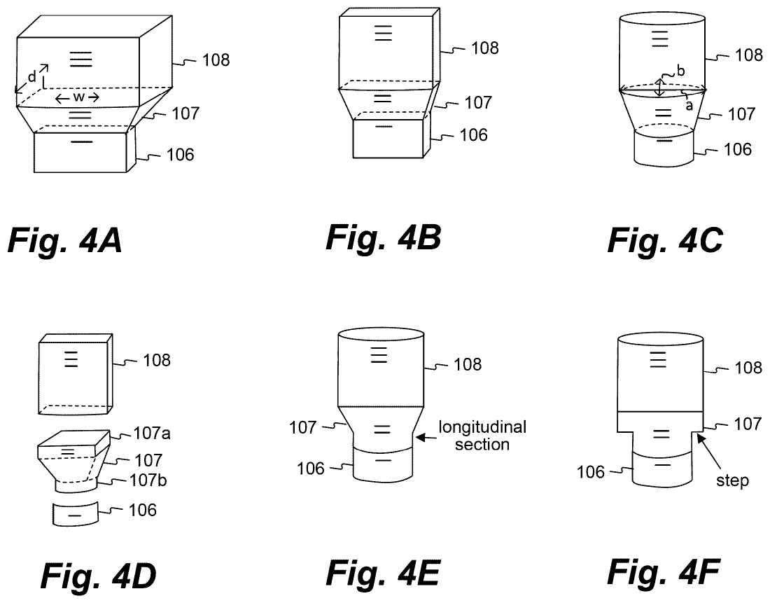

The new pedestal 103 includes new adapter section 107. As shown, the adapter section 107 is between the existing pedestal base 106 and the new pedestal lid 108. The adapter section 107 accommodates any change in size and/or shape between the existing pedestal base 106 and the new pedestal lid 108. For example, the new adapter section 107 may accommodate the size differences described above between the existing pedestal base 106 and the new pedestal lid 108. As shown, in some embodiments, one or more surfaces of the new adapter section 107 may extend diagonally between the existing pedestal base 106 and the new pedestal lid 108. Other arrangements of the new adapter section 107 are described below with respect to FIGS. 4A-4F. In some embodiments, the central axis of the adapter section 107 aligns with the central axis of the existing pedestal base 106 and the new pedestal lid 108. In some embodiments, the adapter section 107 acts as an offset collar between the existing pedestal base 106 and the new pedestal lid 108 to accommodate changes in shape and/or central axes between the existing pedestal base 106 and the new pedestal lid 108.

In some embodiments, the new adapter section 107 may include one or more vents 110b to accommodate the increased heat generation of the new communication equipment. In some situations, these vents 110b may be larger than vents of existing pedestal 101. For example, vents 110a may be longer and/or include a larger opening area than vents on existing pedestal base 106. In other embodiments pedestal 101 may not have included any vents. As further described below, vent(s) 110b allow airflow through the new pedestal lid 108 to cool the new communication equipment through convection.

In some embodiments, the new adapter section 107 may include a keyway or locking mechanism of key mechanism 109a to lock the connection between the new adapter section 107 and the new pedestal lid 108. In some embodiments, the new adapter section 107 may include a keyway or locking mechanism of key mechanism 109b to lock the connection between the new adapter section 107 and the existing pedestal base 106.

In some embodiments, new adapter section 107 may include one or more components to accommodate the communication equipment in new pedestal lid 108. For example, new adapter section 107 may include one or more splitters, taps, and/or hybrid fiber coax (HFC) equipment. Further, new adapter section 107 may include support devices to mount these components, such as struts, clamps, clips and/or mounts. Housing these components and/or support devices in new adapter section 107 saves room in new pedestal lid 108 to accommodate the communication equipment.

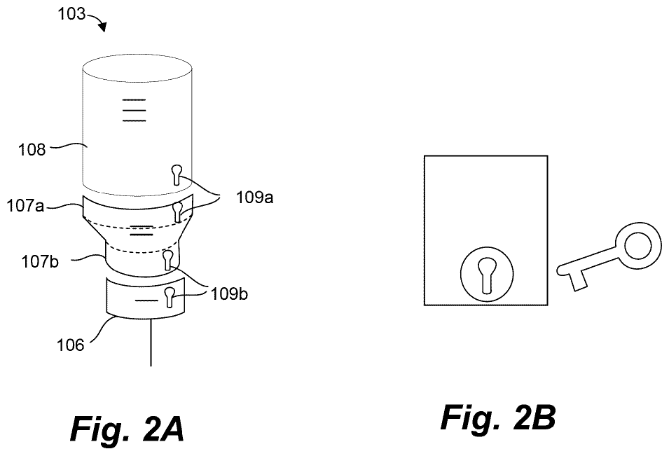

FIGS. 2a-2b illustrate exploded views of the pedestal apparatus components, consistent with disclosed embodiments. FIG. 2a illustrates the component connections between a new pedestal lid 108, new adapter section 107, and existing pedestal base 106. In some embodiments, as shown, the new adapter section 107 may include an upper flange 107a that allows for a secure connection between the new adapter section 107 and new pedestal lid 108. In some embodiments, the upper flange 107a may be sized to allow for a friction fit between the new pedestal lid 108 and the new adapter section 107. For example, in some embodiments, the upper flange 107a may be inset within the bottom of the new pedestal lid 108 and press against the interior of the new pedestal lid 108. In some embodiments, the bottom of the new pedestal lid 108 may be inset within the new adapter section 107 and press against the interior of the new adapter section 107.

As shown, in some embodiments, both the new pedestal lid 108 and the new adapter section 107 include a component of key mechanism 109a that allows the new pedestal lid 108 to be locked to the new adapter section 107. In some embodiments, the new pedestal lid 108 may include a cutout for a keyway and the new adapter section 107 may include the locking mechanism that receives a key and locks the new pedestal lid 108 and the new adapter section 107 together. For example, the new adapter section 107 may include a locking mechanism secured to its interior.

In some embodiments, as shown, the new adapter section 107 may include a lower flange 107b that allows for a secure connection between the new adapter section 107 and the existing pedestal base 106. In some embodiments, the lower flange 107b may be sized to allow for a friction fit between the new adapter section 107 and the existing pedestal base 106. For example, in some embodiments, the lower flange 107b may be inset within the top of existing pedestal base 106 and press against the interior of the existing pedestal base 106. In some embodiments, the top of the existing pedestal base 106 may be inset within the new adapter section 107 and press against the interior of the new adapter section 107.

As shown, in some embodiments, both the existing pedestal base 106 and the new adapter section 107 include a component of key mechanism 109b that allows the existing pedestal base 106 to be locked to the new adapter section 107. In some embodiments, the existing pedestal base 106 may include a cutout for a keyway and the new adapter section 107 may include the locking mechanism that receives a key and locks the existing pedestal base 106 and the new adapter section 107 together. For example, the new adapter section 107 may new include a locking mechanism secured to its interior. The key mechanism 109b included as part of the new adapter section 107 may be configured to work with the portion of key mechanism 109b on existing base 106. For example, a locking mechanism mounted to the new adapter section 107 may be selected based on its ability to interface with an existing keyway on existing base 106.

While the connections between the new lid 108 and the new adapter section 107 and between the new adapter section 107 and the existing base 106 are made through overlapping longitudinal sections, other types of connections may be used. For example, one or both connections may be made by connecting radially extending flanges.

FIG. 2b illustrates an example of a key mechanism 109a and/or 109b. As shown, the key mechanism may include a keyway and a locking mechanism that controls the locking and unlocking between components. For example, in some embodiments the key mechanism may include a Channell Pedestal Security Lock system that receives a P key. In other embodiments, different pedestal lock systems may be used. In some embodiments, key mechanism 109a and/or 109b may include a padlock or a keyed lock. In some embodiments, a security bolt, such as a penta-bolt, may secure new pedestal lid 108 to new adapter section 107 and/or new pedestal lid 108 to existing base 106.

In some embodiments, new pedestal lid 108 may be secured to new adapter section 107 in a manner that is different from the manner in which new adapter section 107 is secured to existing based 106. In other embodiments, both connections are secured in the same manner.

In some embodiments, a single keyway may lock all sections of new pedestal 103 in place. For example, a locking mechanism mounted inside the new pedestal 103 may extend from a single keyway location to secure connections between the existing pedestal base 106 and new adapter section 107 and between the new adapter section 107 and the new pedestal lid 108.

In some embodiments, in addition to or instead of the keyed connection between the existing pedestal base 106 and the new adapter section 107, these sections may be fixed together in other manners. For example, the new adapter section 107 may be riveted, welded, bolted, screwed, or otherwise fastened to the existing pedestal base 106 and/or new pedestal lid 108. In some embodiments, the new adapter section 107 is more permanently fixed to existing pedestal base 106 than it is to new pedestal lid 108. For example, bolts or rivets may connect existing pedestal base 106 to new adapter section 107, and a friction fit and/or keyed connection may connect new adapter section 107 to new pedestal lid 108.

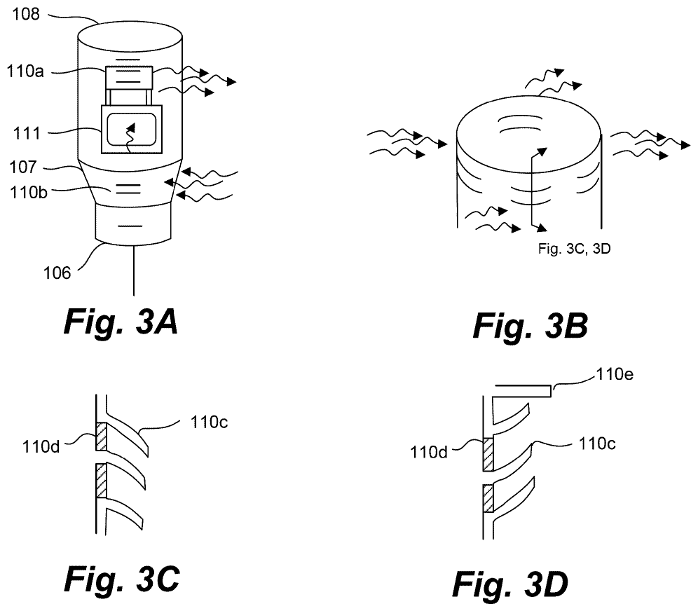

FIGS. 3a-3c illustrate the pedestal apparatus venting components and provided heat dissipation, consistent with disclosed embodiments. FIG. 3a illustrates an example of new communication equipment 111 (e.g., amplifier or node equipment) that may be mounted within the new pedestal lid 108. In some embodiments, all the communication equipment 111 may be mounted within the new pedestal lid 108, and the new adapter section 107 may act as a chase way for communication cables running to/from the communication equipment 111. For example, adapter section 107 may act as a chase way for fiber cables, fiberoptic cables, coax cables, and/or twisted pair cables. In some embodiments, the new adapter section 107 may be free of any communication equipment.

As described above, the new pedestal lid 108 and/or the new adapter section 107 may include vents 110a and 110b. In some embodiments, the new adapter section vent(s) 110b are placed below the communication equipment 111. In some embodiments, the new pedestal lid vent(s) 110a are mounted towards the top of the new pedestal lid 108 (e.g. a vent slat may be located within 4-5 inches from a top face of new pedestal lid 108). The configuration of vents 110a and 110b may accommodate a stack effect ventilation process. Warmer air adjacent to communication equipment 111 may rise and flow through vents 110a, creating a pressure difference that pulls in cooler air flowing through vents 110b. The airflow created through the natural ventilation process helps to keep the communication equipment 111 from overheating, avoiding damage to the equipment. In some embodiments, different vent layouts may be used to accommodate airflow across communication equipment 111.

FIG. 3b illustrates an example vent layout. In some embodiments, as shown in FIG. 3b, vents 110a and/or 110b may include a plurality of slats. In some embodiments, these vents slats are spaced along multiple sides (e.g., one or more vent slats in each quadrant) and/or the entire perimeter of the new pedestal lid 108 and/or the new adapter section 107. The vent layout may allow air to flow sideways across the communication equipment 111. The number of vent slats included in vents 110a and/or 110b may vary based on the heat dissipation required by the communication equipment 111. For example, vents 110a and/or 110b may include more vent slats and/or larger vent slats than existing pedestal 101 to accommodate higher power communication equipment with greater heat generation.

FIG. 3c illustrates an example profile of vent slats 110c of vents 110a and/or vents 110b. As shown, in some embodiments, the vent slats 110c may be angled downwards. In some embodiments, vent slats 110c may be a continuation of the new pedestal lid 108 or the new adapter section 107. For example, in some embodiments the vents slats 110c may be created by a mold used to make the new lid 108 and/or the new adapter section 107. In some embodiments, the vent slats 110c and wall(s) of the new pedestal lid 108 and/or the new adapter section 107 may be cast together. In some embodiments, vent slats 110c may be created by cutting and/or bending portions of the new pedestal lid 108 and/or new adapter section 107.

FIG. 3d illustrates another example profile of vent slats 110c of vents 110a and/or vents 110b. As shown, in some embodiments, the vent slats 110c may be angled upwards. In some embodiments, slats of vents 110b may be angled downward, as shown in FIG. 3c, to accommodate air intake. Further, slats of vents 110a may be angled upwards, as shown in FIG. 3d, to accommodate air exhaust.

In some embodiments, lip 110e may protect vents 110a and/or vents 110b by reducing or preventing ingress of water or debris. In some embodiments, similar to the vents 110a and/or vents 110b, lip 110e vent may be a continuation of the new lid 108 or the new adapter section 107. For example, in some embodiments lip 110e may be created by a mold used to make the new lid 108 and/or new adapter section 107. In some embodiments, the lip 110e, vents 110a, and/or wall(s) of the new lid 108, may be cast together.

In some embodiments, a screen 110d may protect the inside of pedestal 103 from bugs and/or debris entering through the gaps created between the vent slats 110c. For example, screen 110d may include mesh or netting sized to protect the inside of pedestal 103. Screen 110d may be constructed with metal, fiberglass, polyester, and/or any other material that protects the inside of pedestal 103. In some embodiments, screen 110d may be fastened to an interior surface of pedestal 103, such as an inside face of the new adapter section 107 and/or new pedestal lid 108. In some embodiments, screen 110d may be fastened to an exterior surface of the pedestal 103, such as an exterior face of the new adapter section 107 and/or new pedestal lid 108. In some embodiments, screen 110d may be a continuous sheet of material that covers all vent slats 110c included in vent(s) 110a or 110b. In other embodiments, different sheets of screen material may cover one or more vent slats 110c included in vent(s) 110a or 110(b).

FIGS. 4a-4f illustrate example configurations of the pedestal apparatus, consistent with disclosed embodiments. Pedestal 103 may come in a variety of different shapes and configurations.

FIG. 4a illustrates an example configuration of new pedestal 103. For example, as shown, new pedestal 103 may include an existing base 106 and new pedestal lid 108 with rectangular cross sections. The width to depth ratio (w:d) of existing pedestal base 106 may be the same as or different from the width to depth ratio of new pedestal lid 108. New adapter section 107 may connect to existing pedestal base 106 and new pedestal lid 108 through any manner described above, and may be configured to accommodate any change in size and shape between existing pedestal base 106 and new pedestal lid 108.

FIG. 4b illustrates another exemplary configuration of new pedestal 103. For example, as shown, new pedestal 103 may include an existing base 106 and new pedestal lid 108 with square cross sections. New adapter section 107 may connect to existing pedestal base 106 and new pedestal lid 108 through any manner described above, and may be configured to accommodate any change in size between existing pedestal base 106 and new pedestal lid 108.

FIG. 4c illustrates another example configuration of new pedestal 103. For example, as shown, new pedestal 103 may include an existing base 106 and new pedestal lid 108 with circular or ovular cross sections. The major to minor axes ratio (a:b) of existing pedestal base 106 may be the same as or different from the major to minor axes ratio of new pedestal lid 108. New adapter section 107 may connect to existing pedestal base 106 and new pedestal lid 108 through any manner described above, and may be configured to accommodate any change in size and shape between existing pedestal base 106 and new pedestal lid 108.

FIG. 4d illustrates another example configuration of new pedestal 103. As shown, in some embodiments, a cross section shape of existing pedestal base 106 may be different from the a cross section shape of new pedestal lid 108. For example, as shown, existing pedestal base 106 may have a circular or ovular cross section, and new pedestal lid 108 may have a rectangular or square cross section. In other embodiments, existing pedestal base 106 may have a square or rectangular cross section, and new pedestal lid 108 may have a circular or ovular cross section. New adapter section 107 may connect to existing pedestal base 106 and new pedestal lid 108 through any manner described above, and may be configured to accommodate any change in size and shape between existing pedestal base 106 and new pedestal lid 108.

For example, as shown, new adapter section 107 may include upper flange 107a with a first cross sectional shape (e.g., a square or rectangular cross section) configured to connect to new pedestal lid 108. In some embodiments upper flange 107a may be inset within the top of new pedestal lid 108. New adapter section 107 may further include lower flange 107b with a second cross sectional shape (e.g., a circular or ovular cross section) configured to connect to existing pedestal base 106. In some embodiments, lower flange 107b may be inset within existing pedestal base 106.

FIG. 4e illustrates another example configuration of new pedestal 103. As shown, in some embodiments, the new adapter section 107 may include one or more longitudinal surfaces that align with the existing pedestal base 106 and/or the new pedestal lid 108. In some embodiments, as shown, the longitudinal section may align with existing base 106 and may be followed by a diagonally extending surface to accommodate changes in size or shape between existing pedestal base 106 and new pedestal lid 108. In other embodiments, the longitudinal section may align with new pedestal lid 108 and may be followed by a diagonally extending surface to accommodate changes in size or shape between new pedestal lid 108 and existing pedestal base 106.

FIG. 4f illustrates another example configuration of new pedestal 103. As shown, in some embodiments, the new adapter section 107 may include one or more steps that are perpendicular to a surface of new pedestal lid 108 or existing pedestal base 106. These steps may accommodate a change in size and or shape between existing pedestal base 106 and new pedestal lid 108. These steps may be located at the connection between the new pedestal lid 108 and new adapter section 107, at the connection between the new adapter section 107 and the existing pedestal base 106, and/or in between the connections (as shown).

While not shown, in some embodiments, new adapter section 107 may accommodate a reduction in size from existing pedestal 101 to new pedestal lid 108, a cap, or cover piece. For example, a surface of new adapter section 107 may be angled diagonally inwards and/or include one or more steps to accommodate a reduction in size between existing base 106 and new pedestal lid 108, a cap, or cover piece. This configuration may be beneficial in a situation where communication equipment is being removed and replaced with taps. The smaller pedestal lid, cap, or cover piece may be more aesthetically pleasing.

In some embodiments, the size and shape of new adapter section 107 may additionally be configured based on cooling requirements for communication equipment 111. For example, a size and shape of new adapter section 107 may be configured to accommodate a desired number and/or size of vents to provide sufficient cooling. For example, a surface of new adapter section 107 may be angled in a manner that increases the air flow through one or more vents 110b (e.g., as determined through experimental tests).

In some embodiments, the size and shape of new adapter section 107 may additionally be configured based on requirements of components and/or cabling within the new adapter section 107. For example, a volume of the new adapter section 107 may be sized to accommodate one or more splitters, taps, and/or hybrid fiber coax (HFC) equipment. For example, a length of new adapter section 107 spanning from existing base 106 to new pedestal lid 108 may be sized to accommodate components and/or cabling within the new adapter section 107.

While pedestal 103 is described above as enclosing communication cables, in some embodiments pedestal 103 may enclose any other type of electrical equipment. Therefore, electrical distribution equipment upgrades may be performed without removing an existing pedestal base 106 and associated components.

The foregoing description has been presented for purposes of illustration. It is not exhaustive and does not limit the invention to the precise forms or embodiments disclosed. Modifications and adaptations of the invention will be apparent to those skilled in the art from consideration of the specification and practice of the disclosed embodiments of the inventions disclosed herein. The features and advantages of the disclosure are apparent from the detailed specification, and thus, it is intended that the appended claims cover all systems and methods falling within the true spirit and scope of the disclosure. As used herein, the indefinite articles “a” and “an” mean “one or more. ” Similarly, the use of a plural term does not necessarily denote a plurality unless it is unambiguous in the given context. Words such as “and” or “or” mean “and/or” unless specifically directed otherwise. As used herein, unless specifically stated otherwise, being “based on” may include being dependent on, being interdependent with, being associated with, being defined at least in part by, being derived from, being influenced by, or being responsive to. As used herein, “related to” may include being inclusive of, being expressed by, being indicated by, or being based on. Further, since numerous modifications and variations will readily occur from studying the present disclosure, it is not desired to limit the disclosure to the exact construction and operation illustrated and described, and accordingly, all suitable modifications and equivalents may be resorted to, falling within the scope of the disclosure.

Other embodiments will be apparent to those skilled in the art from consideration of the specification and practice of the implementations disclosed herein. It is intended that the architectures and circuit arrangements shown in figures are only for illustrative purposes and are not intended to be limited to the specific arrangements and circuit arrangements as described and shown in the figures. It is also intended that the specification and examples be considered as exemplary only, with the true scope and spirit of the invention being indicated by the following claims. The foregoing description has been presented for purposes of illustration. It is not exhaustive and does not limit the invention to the precise forms or embodiments disclosed. Modifications and adaptations of the invention will be apparent to those skilled in the art from consideration of the specification and practice of the disclosed embodiments of the inventions disclosed herein.

1. A pedestal apparatus, comprising:
a lid component having a first cross sectional area;
a base component having a second cross sectional area smaller than the first cross sectional area,
an adapter component configured to connect the lid component to the base component and enclose communication cables running from the base component to the lid component.

2. The pedestal apparatus of claim 1, further comprising a ground support structure secured inside the base component and configured to secure the pedestal apparatus to the ground.

3. The pedestal apparatus of claim 2, wherein the ground support structure is a rod.

4. The pedestal apparatus of claim 2, wherein the ground support structure is configured to span from a mounting location in the ground through the lid component and support equipment in the lid component.

5. The pedestal apparatus of claim 1, wherein the lid component cross section is at least one of a square, rectangle, circle, or oval.

6. The pedestal apparatus of claim 1, wherein the base component cross section is at least one of a square, rectangle, circle, or oval.

7. The pedestal apparatus of claim 1,
wherein a cross section of the lid component is a first shape,
wherein the cross section of the base component is a second shape, different from the first shape, and
wherein a top of the adapter component aligns with the first shape of the lid component and a bottom of the adapter component aligns with the second shape of the base component.

8. The pedestal apparatus of claim 1, wherein the adapter component includes a surface extending diagonally from the base component to the lid component.

9. The pedestal apparatus of claim 1, wherein the adapter component includes a flange configured to be inset within the lid component to achieve a friction connection between the lid component and the adapter component.

10. The pedestal apparatus of claim 1, wherein the adapter component includes a flange configured to be inset within the base component to achieve a friction connection between the adapter component and the base component.

11. The pedestal apparatus of claim 1, wherein the lid component and the adapter component each includes a portion of a locking mechanism to lock the lid component to the adapter component.

12. The pedestal apparatus of claim 1, wherein the base component and the adapter component each includes a portion of a locking mechanism to lock the base component to the adapter component.

13. The pedestal apparatus of claim 1, wherein the lid component comprises at least one vent.

14. The pedestal apparatus of claim 1, wherein the adapter component comprises at least one vent.

15. The pedestal apparatus of claim 1, wherein the adapter component comprises at least one vent on each quadrant of the adapter component.

16. The pedestal apparatus of claim 1,
wherein the adapter component comprises at least one vent configured to intake air; and
wherein the lid component comprises at least one vent configured to exhaust air.

17. The pedestal apparatus of claim 1, wherein the adapter component comprises a plurality of vent slats.

18. The pedestal apparatus of claim 17, wherein the adapter component comprises a screen to cover openings into the pedestal apparatus created by the plurality of slats.

19. The pedestal apparatus of claim 1, wherein the adapter is made of at least one of: plastic, fiberglass, or steel.

20. A pedestal apparatus adapter, comprising:
a bottom portion having a first cross sectional area and configured to align with a base component;
a top portion having a second cross sectional area larger than the first cross sectional area, the top portion being configured to align with a lid component; and
a surface spanning from the bottom portion to the top portion, the surface being configured to enclose communication cables running from the base component to the lid component.

21. A method of upgrading pedestal equipment, comprising:
removing an existing pedestal lid from an existing pedestal base;
installing an adapter component configured to accommodate a difference in size between
a first cross sectional area of the existing pedestal base and a second cross sectional area of the new pedestal lid,
wherein the second cross sectional area is larger than the first cross sectional area;
and
installing the new pedestal lid.

22. The method of claim 21, wherein the new pedestal lid comprises more ventilation area than the existing pedestal lid.
